(19) United States
(12) Patent Application Publication
(10) Pub. No.: US 2005/0280476 A1
(43) Pub. Date: Dec. 22, 2005

(54) Filter control apparatus and filter system

(75) Inventors: Kazuhide Abe, Kanagawa-ken (JP); Michihiko Nishigaki, Kanagawa-ken (JP); Toshihiko Nagano, Kanagawa-ken (JP); Ryoichi Ohara, Kanagawa-ken (JP); Hiroshi Yoshida, Kanagawa-ken (JP); Hiroshi Tsurumi, Kanagawa-ken (JP); Takashi Kawakubo, Kanagawa-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/151,343

(22) Filed: Jun. 14, 2005

(30) Foreign Application Priority Data
Jun. 15, 2004 (JP) 2004-177443

(51) Int. Cl. H03L 7/00

(52) U.S. Cl. 331/17

(57) ABSTRACT

A filter control apparatus which controls a frequency variable filter capable of changing a transmission band width by controlling a capacitance of at least a portion of a plurality of voltage variable capacitors connected in series and parallel to a resonator has an input unit, and a filter control circuit. The input unit inputs a reference signal with a predetermined reference frequency to the frequency variable filter. The filter control circuit controls a center frequency and the transmission band width of the frequency variable filter by detecting a phase change generated when the reference signal passes through the frequency variable filter and by variably controlling the capacitance of at least a portion of the voltage variable capacitor by using a direct voltage in proportion to the phase change.

### CROSS REFERENCE TO RELATED APPLICATIONS

This application is based upon and claims the benefit of priority from the prior Japanese Patent Application No. 2004-177443, filed on Jun. 15, 2004, the entire contents of which are incorporated herein by reference.

### BACKGROUND OF THE INVENTION

1. Field of the Invention

The present invention relates to a filter control apparatus and a filter system, which have a resonator.

2. Related Art

Recently, market of information terminals using radio transmission such as cellular phones and wireless LANs has been growing, and services using radio transmission has been sophisticated. It is predicted that wireless LAN systems which transmit data wirelessly at high speed between computers will be rapidly widespread in the near future. The wireless LAN systems generally use a high frequency having gigahertz band.

Architectures of receivers used for the wireless LAN systems can be categorized into a heterodyne type and a direct conversion type. Most of the wireless LAN systems adopt either of the two architectures. Both of the two architectures use a band selection filter (band-pass filter) capable of passing only a specific frequency band in the high frequency.

Hereinafter, the band means a specific frequency band allocated to user based on a certain communication standard. The specific frequency band includes multiple narrower channel bands allocated to each user. After a specific frequency band is selected, a down-conversion mixer converts the frequency into an intermediate frequency or a base band. And then a channel selection filter or a digital filter extracts generally only a signal with a channel band allocated to each user.

Instead of conventional receiver which extract a desirable frequency by two steps as described above, the present inventor researches a possibility of a frequency variable channel filter which can directly extract a desirable channel band at radio frequency by only one step. If such a tunable filter capable of selecting channels is realized, signal processing at the intermediate frequency band or the base band are largely reduced, thereby downsizing a receiver and reducing cost.

In order to realize the tunable filter mentioned above, a method in which a bias voltage is applied to a thin film piezoelectric resonator made of a ferroelectric material to obtain variable frequencies has been disclosed in Japanese Patent Laid-Open No. 2003-168955.

As the other approach, there is a method using a frequency variable filter having a FBAR (Film Bulk Acoustic Resonator) and a variable capacitor. This filter has one resonance unit in which a first variable capacitor is connected in parallel to the FBAR and a second variable capacitor is connected in series to the FBAR. The filter has the resonance units connected in series and parallel in a ladder shape. When capacitances of the first and second variable capacitors are adjusted to proper values, it is possible to obtain a desirable passband property of the filter.

However, capacitances of the variable capacitors necessary to obtain the appropriate passband of the filter cannot be necessarily expressed by a simple function of a center frequency. It is necessary to control capacitances of the first and second variable capacitors independently to each other.

As the other problem, a junction capacitance of semiconductors or a variable MEMS capacitor may be used for this purpose. In each case, however, the capacitance may fluctuate on variations of fabrication conditions. Since the FBAR or as SAW (Surface Acoustic Wave) may be used for the resonator, the frequency property slightly changes according to temperature. This is called as a temperature drift.

### SUMMARY OF THE INVENTION

In order to solve the above-described problem, an object of the present invention is to provide a filter control apparatus and a filter system capable of adjusting a center frequency and a transmission band width of a frequency variable filter with high accuracy.

According to one aspect of the present invention, a filter control apparatus which controls a frequency variable filter capable of changing a center frequency and a transmission band width by controlling a capacitance of at least a portion of a plurality of voltage variable capacitors connected in series and parallel to resonators, comprising:
an input unit which inputs a reference signal with a predetermined reference frequency to the frequency variable filter; and
a filter control circuit which controls a center frequency and the transmission band width of the frequency variable filter by detecting a phase change generated when the reference signal passes through the frequency variable filter, and by variably controlling the capacitance of at least a portion of the voltage variable capacitor by using a control voltage in proportion to the phase change.

Furthermore, according to one aspect of the present invention, a filter system, comprising:
a frequency variable filter capable of changing a center frequency and a transmission band width by controlling capacitances of a plurality of voltage variable capacitors connected in parallel and series to a resonator; and
a filter control circuit which controls a center frequency and the transmission band width of the frequency variable filter,
wherein the filter control circuit has a capacitance control circuit which controls the center frequency and the transmission band width of the frequency variable filter based on the capacitances of the plurality of voltage variable capacitors when a switching circuit, which selects whether to input a reference signal with a predetermined reference frequency into the frequency variable filter, or not, selects to input the reference signal into the frequency variable filter.

Furthermore, according to one aspect of the present invention, a filter system, comprising:
a first frequency variable filter capable of changing a center frequency and transmission band width by controlling capacitances of a plurality of voltage variable capacitors connected in parallel and series to a resonator; and
a voltage control oscillator which has a second frequency variable filter having the same configuration as that of the first frequency variable filter; and
a phase locked loop circuit which generates a control voltage based on a phase difference between an oscillation output signal of the voltage control oscillator and a predetermined reference signal,
wherein the voltage control oscillator controls center frequencies and transmission band widths of the first and second frequency variable filters based on the same control voltage.

### BRIEF DESCRIPTION OF THE DRAWINGS

FIG. 1 is a block diagram showing a schematic configuration of a filter system according to a first embodiment of the present invention.

FIG. 2 is a circuit diagram showing one embodiment of a circuit configuration of the frequency variable filter 1.

FIG. 3 is a diagram showing frequency dependencies of an absolute value of an S21 parameter and a phase.

FIGS. 4(a), 4(b) and 4(c) are a waveform diagram showing input and output voltage waveforms of the frequency variable filter 1.

FIG. 5 is a diagram showing passband properties and phase properties of the filters in the case that the capacitance of the variable capacitor C1 is 10% larger or 10% smaller in a state of fixing the capacitance of the variable capacitor C2 shown in FIG. 2.

FIG. 6 is a diagram showing passband properties and phase properties of the filters in the case the capacitance of the variable capacitor C2 is 10% larger or 10% smaller in a state of fixing the capacitance of the variable capacitor C1.

FIG. 7 is a circuit diagram showing one example of a specific configuration.

FIG. 8 is a block diagram showing a schematic configuration of a filter system according to a second embodiment of the present invention.

FIG. 9 is an operational timing diagram of the filter loop.

FIG. 10 is a block diagram showing an example of internal configuration of a voltage control oscillator which generates a reference signal.

FIG. 11 is a block diagram showing one example of a PLL circuit using the voltage control oscillator in FIG. 10 as the local oscillator.

### DETAILED DESCRIPTION OF THE INVENTION

Hereafter, a filter control apparatus and a filter system according to the present invention will be described more specifically with reference to the drawings.

### First Embodiment

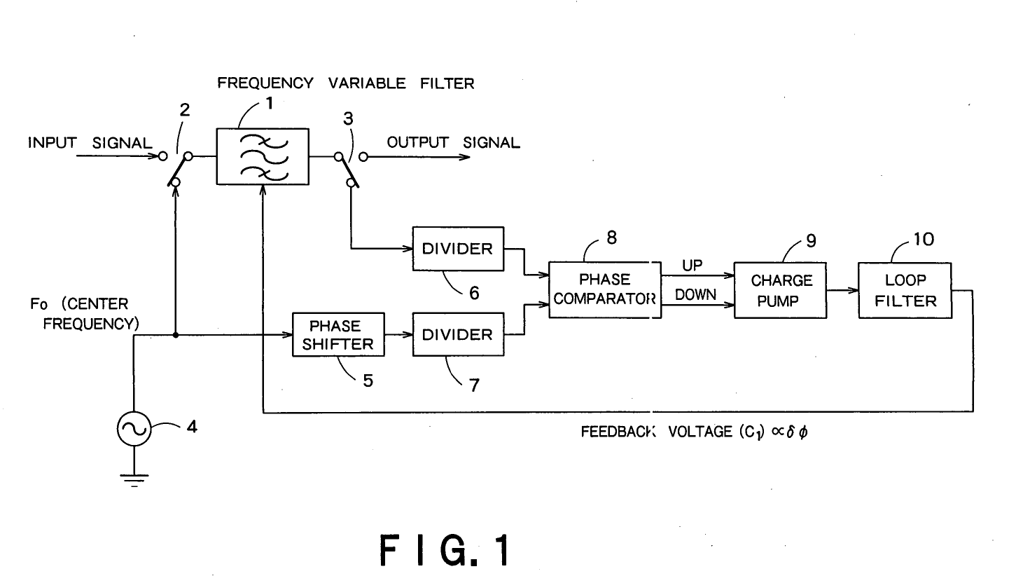

FIG. 1 is a block diagram showing a schematic configuration of a filter system according to a first embodiment of the present invention. The filter system of FIG. 1 has a frequency variable filter 1, a first switch 2 which switches signals inputted to the frequency variable filter 1, a second switch 3 which switches output directions of the frequency variable filter 1, a local oscillator 4 which generates a reference signal, a phase shifter 5, dividers 6 and 7, a phase comparator 8, a charge pump 9 and a loop filter 10.

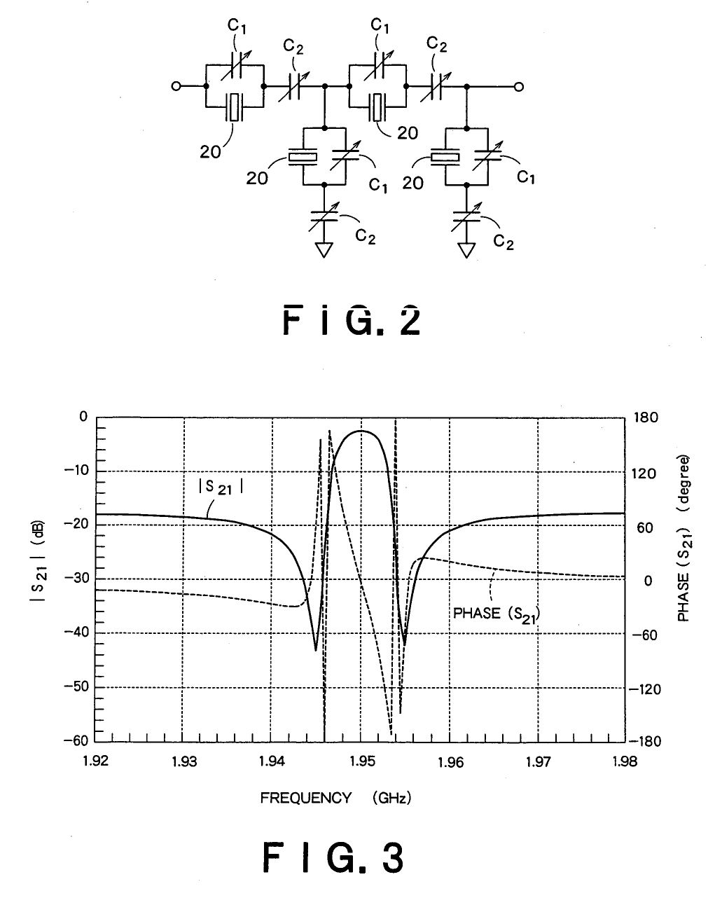

FIG. 2 is a circuit diagram showing one embodiment of a circuit configuration of the frequency variable filter 1. The frequency variable filter 1 in FIG. 2 is a ladder type filter which has a resonator 20, and variable capacitors C1 and C2 connected in parallel and series to the resonator 20. The resonator 20 may be embodied by, for example, an FBAR (Film Bulk Acoustic Resonator). Otherwise, the resonator 20 may be embodied by, for example, an SAW (Surface Acoustic Wave) resonator, a crystal resonator, a piezo-ceramic resonator, a MEMS resonator, and so on. In this embodiment, it is assumed that the variable capacitors C1 and C2 are adjusted to desirable capacitances by a certain means.

FIG. 3 is a diagram showing frequency dependencies of both an absolute value and a phase of an S21 parameter when capacitances of the variable capacitors C1 and C2 are adjusted so that the center frequency of the frequency variable filter 1 becomes 1.950 GHz

An insertion loss is minimized in vicinity of the center frequency, the phase becomes zero at the center frequency, the phase gets ahead at frequencies lower than the center frequency, and the phase gets behind at frequencies higher than the center frequency.

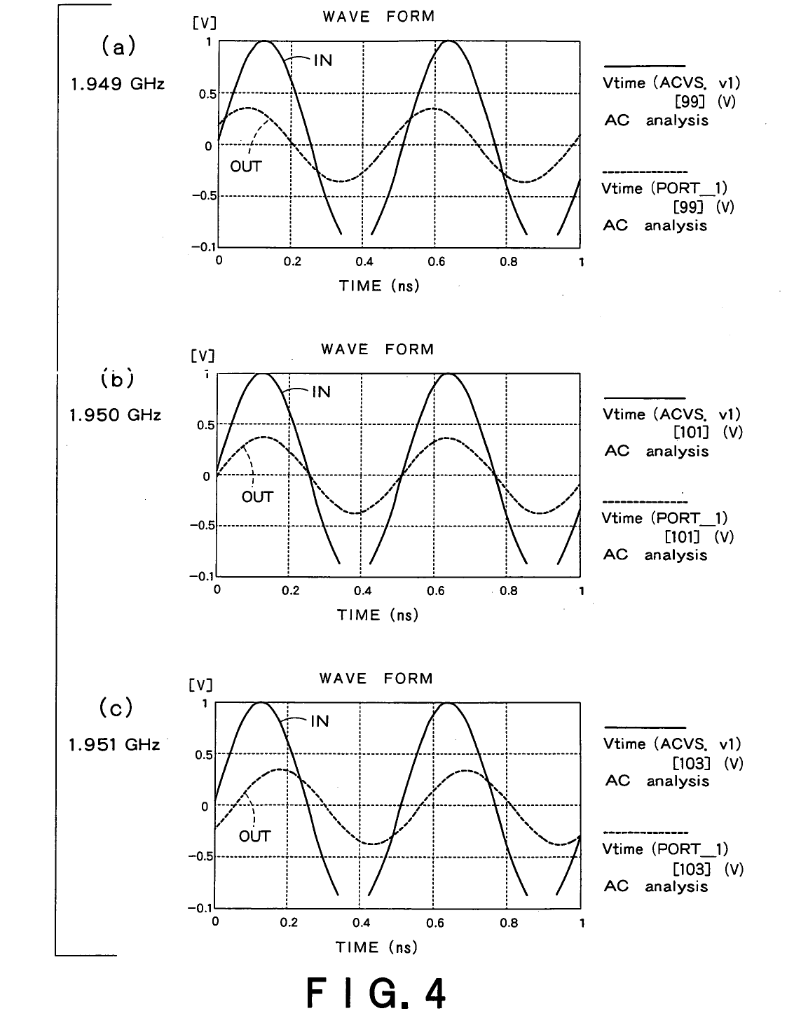

FIG. 4 is a waveform diagram showing input and output voltage waveforms of the frequency variable filter 1. FIG. 4(a) shows an input voltage waveform IN and an output voltage waveform OUT after passing the filter when a sine wave voltage is inputted at a frequency 1.949 GHz slightly lower than the center frequency 1.950 GHz. FIG. 4(b) shows the input voltage waveform IN and the output voltage waveform OUT after passing the filter when the sine wave voltage is inputted at the center frequency 1.950 GHz. FIG. 4(c) shows the input voltage waveform IN and the output voltage waveform OUT after passing the filter when the sine wave voltage is inputted at a frequency 1.951 GHz slightly higher than the center frequency 1.950 GHz.

The phases of the input voltage waveform and the output voltage waveform coincide with each other at the center frequency 1.950 GHz. The phase of the output voltage waveform OUT is slightly later than that of the input voltage waveform IN at the frequency 1.949 GHz. The phase of the output voltage waveform OUT is slightly faster than that of the input voltage waveform IN at the frequency 1.951 GHz.

According to these results, it is possible to grasp how much the center frequency deviates to which direction, by detecting a phase difference between the signal waveforms before and after passing the frequency variable filter 1 in FIG. 2 by the phase comparator 8.

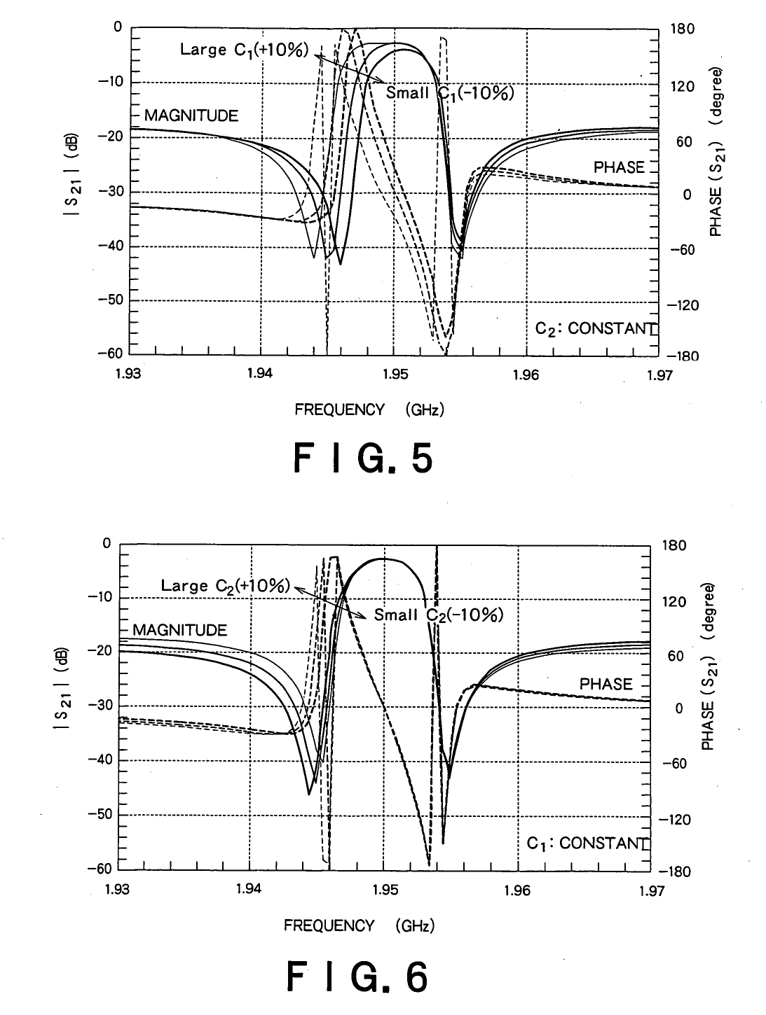

FIG. 5 is a diagram showing passband properties and phase properties of the filters in the case that the capacitance of the variable capacitor C1 is 10% larger or 10% smaller in a state of fixing the capacitance of the variable capacitor C2 shown in FIG. 2. When the capacitance of the variable capacitor C1 is 10% smaller, the transmission band width narrows, and the center frequency deviates in high frequency side. Conversely, when the capacitance of the variable capacitor C1 is 10% larger, the transmission band width enlarges, and the center frequency deviates in low frequency side.

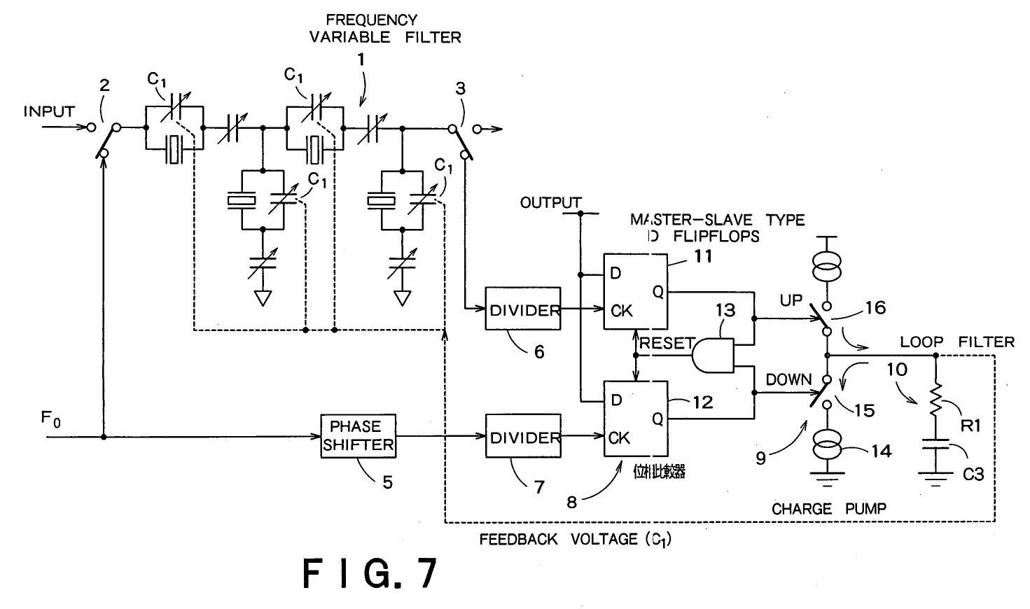

FIG. 6 is a diagram showing passband properties and phase properties of the filters in the case the capacitance of the variable capacitor C2 is 10% larger or 10% smaller in a state of fixing the capacitance of the variable capacitor C1 in the frequency variable filter of FIG. 2. Compared with FIG. 5, variation of the transmission band width and variation of the center frequency are small, even if the capacitance of the variable capacitor C1 is 10% smaller or 10% larger.

As apparent from the results of FIGS. 5 and 6, it is effective to accurately control the capacitance of the variable capacitor C1 connected in parallel to the resonator 20, in order to accurately control the transmission band width and the center frequency of the frequency variable filter 1 in FIG. 3.

According to the phase properties in FIG. 5, when the capacitance of the variable capacitor C1 is 10% smaller, the phase φ (φ>0) of the output signal becomes faster than that of the input signal at the center frequency 1.950 GHz. When the capacitance of the variable capacitor C1 is 10% larger, the phase φ (φ<0) of the output signal becomes later than that of the input signal at the center frequency.

As described above, the frequency variable filter 1 in FIG. 1 compares the phase of the signal before passing the signal at a desirable center frequency to the filter with the phase of the signal after passing the filter, and feedbacks the voltage depending on the phase difference to the variable capacitor C1, thereby obtaining desirable center frequency and frequency band with high accuracy.

The signal inputted to the phase comparator 8 in FIG. 1 is preferably a divisional signal divided by the divider 6 with the same divisional ratio N. When a delay of the phase is generated due to wiring patterns in the frequency variable filter 1, the output of the local oscillator 4 is preferably adjusted by the phase shifter 5 so that the input to the phase comparator 8 is not affected by the phase delay.

FIG. 7 is a circuit diagram showing one example of a specific configuration. The phase comparator 8 in FIG. 7 has master-slave type D flipflops 11 and 12, and a logic operation AND circuit 13. The flipflops 11 and 12 outputs an Up signal or a Down signal having pulse widths in proportion to the phase difference in accordance with advance or delay of the phase. The Up signal and the Down signal are inputted to the charge pump 9.

The charge pump 9 in FIG. 7 has a constant current source 14 and switches 15 and 16. The charge pump 9 charges or discharges the electric charge of a capacitor C3 in the loop filter 10 in accordance with pulse widths of the Up signal and the Down signal.

The loop filter 10 has the capacitor C3 and a resistor R1. The capacitor C3 accumulates the electric charge supplied from the charge pump 9 so that the output voltage does not change sharply. The output voltage of the loop filter 10 is fedback to the frequency variable filter 1 as a feedback voltage. The capacitance of the variable capacitor C1 in the frequency variable filter 1 is controlled by the feedback voltage.

In this way, the circuit in FIG. 7 adjusts the capacitance of the variable capacitor C1 in the frequency variable filter 1 by feedback control based on the output voltage of the loop filter 10. Therefore, it is possible to control the center frequency and the bandwidth of the frequency variable filter 1 at high accuracy.

If the phase of the oscillation frequency in the local oscillator 4 is locked by using a temperature-compensated crystal oscillator and a PLL (Phase Locked Loop) circuit not shown to compensate temperature fluctuation, it is possible to consequently keep the center frequency and the frequency band of the frequency variable filter 1 constant against temperature fluctuation.

After the phase locked loop attained a constant state, the first and second switches 2 and 3 are switched, and a signal for communication can be passed through the frequency variable filter 1. In this time, by opening the switches in the charge pump 9, it is possible to adopt a circuit configuration which holds the electric charge accumulated in the capacitor in the loop filter 10. Therefore, even after the feedback control by the PLL circuit is finished, a voltage at both ends of the capacitor C3, i.e. the control voltage of the capacitor C1 can be held to substantially a constant value for a certain time. Subsequently, the first and second switches 2 and 3 are sometimes turned over to adjust the capacitance of the variable capacitor C1 in the frequency variable filter 1. Therefore, it is possible to reduce deviation of the center frequency and the transmission band width.

As describe above, according to the first embodiment, the capacitance of the variable capacitor C1 in the frequency variable filter 1 is controlled by the phase locked loop. Therefore, it is possible to control the center frequency and the transmission band width of the frequency variable filter 1 at high accuracy.

### Second Embodiment

A second embodiment changes how to control the frequency variable filter 1 after and before an oscillator loop for generating a reference signal is stabilized.

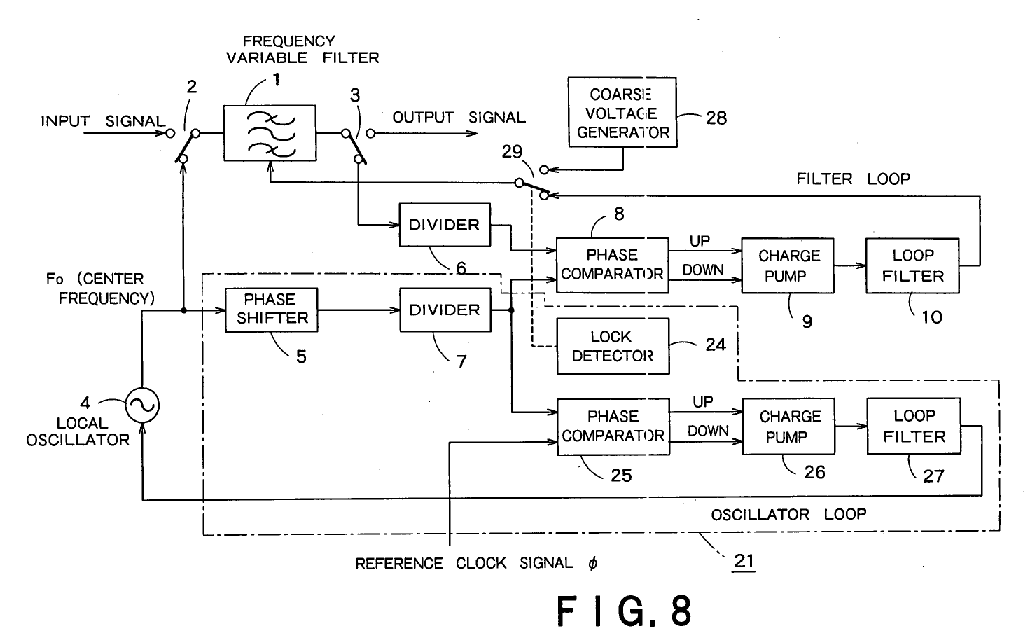

FIG. 8 is a block diagram showing a schematic configuration of a filter system according to a second embodiment of the present invention. The filter system in FIG. 8 has an oscillation control circuit 21 which controls a local oscillator 4, in addition to the configuration of FIG. 1.

The oscillation control circuit 21 has a local oscillator 4 composed of a voltage control oscillator, a phase shifter 5, a divider 7, a lock detector 24, a phase comparator 25, a charge pump 26 and a loop filter 26. Hereinafter, a control system including the divider 6 which controls the center frequency and the bandwidth of the frequency variable filter 1, the phase comparator 8, the charge pump 9 and the loop filter 10 is called as a filter loop, and a control system including the oscillation control circuit 21 is called as an oscillator loop.

The filter loop has a coarse adjustment voltage generator 28 which conducts coarse adjustment of the frequency variable filter 1, and a adjustment switch 29 which switches whether to conduct coarse adjustment or fine adjustment of the frequency variable filter 1, in addition to the configurations of FIG. 1.

The phase comparator 25 in the oscillator loop detects a phase difference between a divisional signal of the reference signal outputted from the local oscillator 4 and a reference clock signal φ. The reference clock signal φ is generated by a temperature-compensated crystal oscillator not shown. The crystal oscillator has extremely high frequency accuracy, and high temperature stability of the frequency. Error information obtained by the phase comparator 25 is fedback to the local oscillator 4 via the charge pump 26 and the loop filter 27. Therefore, it is possible to obtain high stable and high accurate oscillation frequency in the local oscillator 4.

According to the present embodiment, a partial circuit block in the filter loop and the oscillator loop, i.e. the phase shifter 5 and the divider 7 are shared with the filter loop and the oscillator loop. Therefore, it is possible to downsize the circuit volume, compared with the case of individually providing the phase shifters and the dividers in the filter loop and the oscillator loop.

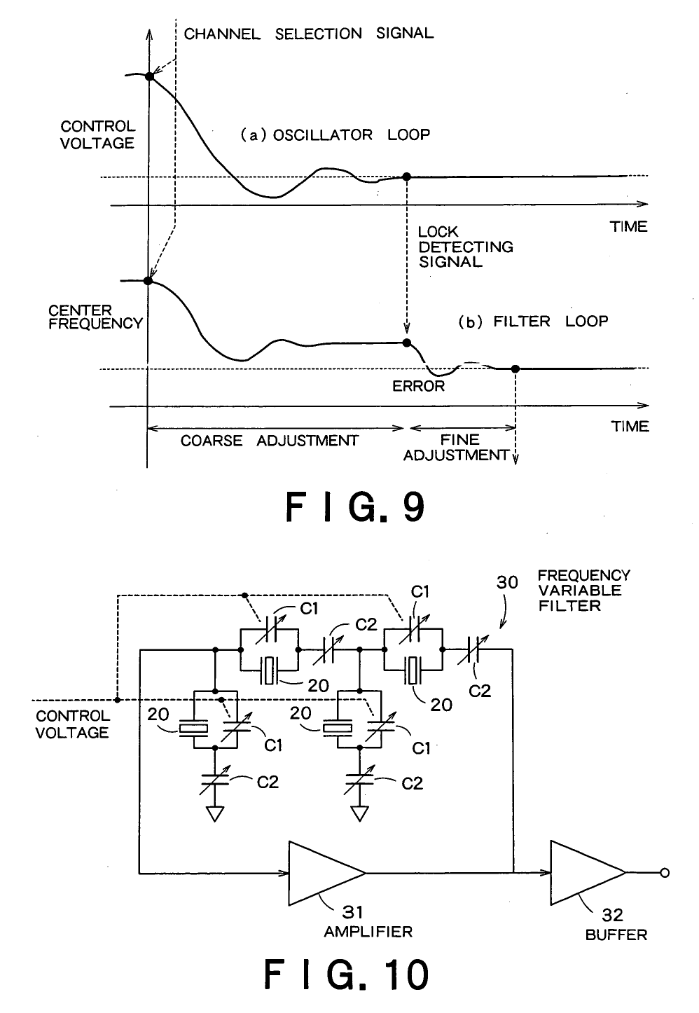

FIG. 9 is an operational timing diagram of the filter loop. FIG. 9 shows the operational timing in the case of transiting from a state that a certain channel is selected, to a state that the other channel is selected. When a channel selection signal is received from a base band circuit not shown, a divisional ratio of the divider 6 changes, and the phase comparator 8 detects the phase difference. While the oscillator loop is conducting the feedback control with respect to the oscillation frequency of the local oscillator 4, the filter loop does not conduct the feedback control using a closed loop at high accuracy, but conducts coarse frequency adjustment using an open loop, i.e. coarse adjustment of the center frequency of the filter. At this moment, the feedback control is not conducted. Accordingly, a minor difference between a desirable frequency and the center frequency of the filter may exist.

When the feedback control using the oscillator loop is completed, and the phase of the oscillation frequency of the local oscillator 4 is locked, a lockup signal is detected, and the filter loop starts the feedback control. The frequency error which could not control by the coarse adjustment is reduced, and it is possible to conduct a high accurate control.

By the above operational timing, it is possible to conduct the coarse adjustment of the filter loop in advance until the oscillator loop is stabilized. Therefore, it is possible to largely shorten a time when the center frequency of the frequency variable filter 1 attain a desirable value.

As described above, the second embodiment has the filter loop and the oscillator loop. Until operation of the oscillator loop is stabilized, the filter loop conducts the coarse adjustment by using the frequency variable filter 1, and the filter loop conducts the fine adjustment of the frequency variable filter 1 after the operation of the oscillator loop is stabilized. Therefore, it is possible to control the center frequency and the transmission band width of the frequency variable filter 1 at short time and high accuracy. Since the filter loop and the oscillator loop shares at least a portion of the circuit components, it is possible to downsize the circuit volume.

### Third Embodiment

A third embodiment uses the control voltage outputted from the loop filter in both of the filter loop and the oscillator loop.

FIG. 10 is a block diagram showing an example of internal configuration of a voltage control oscillator which generates a reference signal. The voltage control oscillator in FIG. 10 has a frequency variable filter 30, an amplifier 31 and a buffer amplifier 32. Only the frequency component passing through the frequency variable filter 30 is fedback to the input of the amplifier 3130.

The phase property of the frequency variable filter 1 in the voltage control oscillator of FIG. 10 is the same as that of FIG. 5, i.e. the insertion loss becomes small in the center frequency of the passband of the frequency variable filter, and the phase difference of the input and the output is zero.

If the phase difference of the input and the output of the amplifier 31 is, for example, zero, and a voltage gain is enough large, this circuit oscillates at a frequency in which the phase difference property of the frequency variable filter 1 is zero, i.e. at a center frequency of the transmission band in the frequency variable filter 1. It is assumed that a desirable oscillation frequency is 1.95 GHz. When the capacitance of the variable capacitor C1 connected in parallel to the resonator 20 in the frequency variable filter 1 is a proper value, the center frequency of the filter is 1.95 GHz, and the oscillator oscillates at a desirable frequency.

However, when the variable capacitor C1 is 10% larger than the desirable value, the frequency that the phase is zero becomes slightly smaller than 1.95 GHz, as shown in FIG. 5. Conversely, when the variable capacitor C1 is 10% smaller than the desirable value, the frequency that the phase is zero becomes slightly larger than 1.95 GHz.

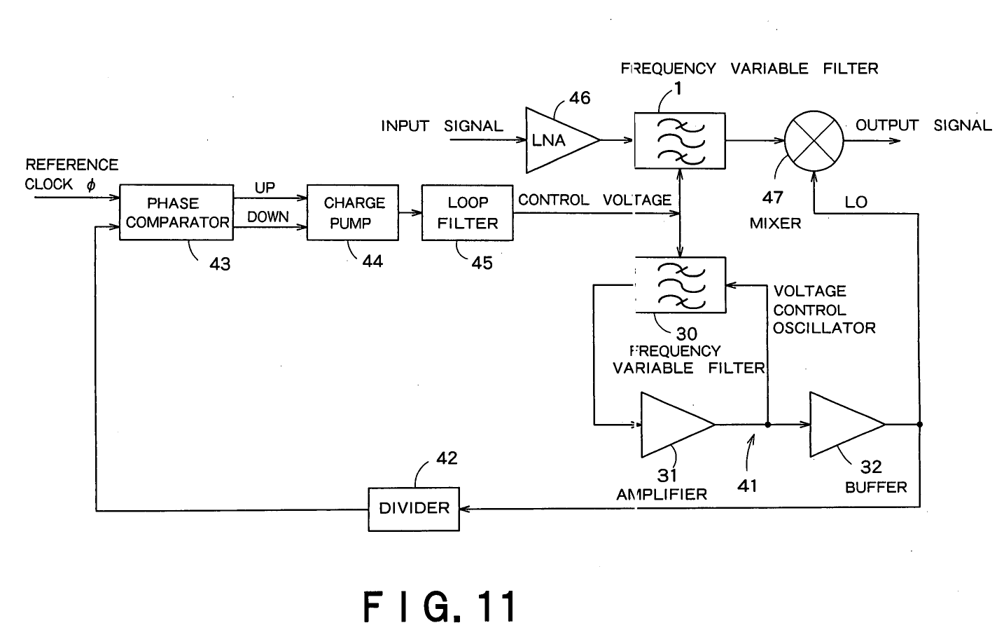

FIG. 11 is a block diagram showing one example of a receiver circuit using the voltage control oscillator in FIG. 10 as the local oscillator. A PLL circuit in FIG. 11 has a voltage control oscillator 41 composed of a frequency variable filter 30, an amplifier 31 and a buffer amplifier 32, a divider 42, a phase comparator 43, a charge pump 44, a loop filter 45, an LNA (Low Noise Amplifier) 46, a frequency variable filter 1 and a mixer 47.

The PLL circuit in FIG. 11 detects the frequency difference and feedbacks a control voltage based on the detected frequency difference to the valuable capacitor C1 in the frequency variable filter 30 functioning as a phase control element in the voltage control oscillator 41, when the oscillation frequency of the voltage control oscillator 41 is too much larger or smaller than the desirable frequency. Accordingly, when the feedback loop operates normally, a stable state is obtained and the phase is locked, it is possible to coincide the oscillation frequency of the voltage control oscillator 41 with the desirable frequency.

The receiver circuit in FIG. 11 uses the frequency variable filter 1 having the same configuration as that of the filter variable filter 30 functioning as a phase control element of the voltage control oscillator 41, as the passband filter for filtering the communication signal. The output signal of the LNA 46 is inputted to the frequency variable filter 1, and the output signal of the frequency variable filter 1 is inputted to the mixer for down conversion.

On the other hand, the reference signal generated by the voltage control oscillator 41 is inputted to the other input terminal of the mixer 47 as the local oscillation signal (LO). Therefore, a frequency of a high frequency signal is converted into the base band signal or intermediate signal.

According to the third embodiment, the same control voltage generated by the loop filter 10 is applied to the frequency variable filter 1 and the frequency variable filter 30 in the voltage control oscillator. Therefore, it is possible to coincide the oscillation frequency of the voltage control oscillator 41 with the center frequency of the passband of the frequency variable filter 1.

As described above, according to the third embodiment, it is possible to control the frequency variable filter 1 based on the control voltage generated by the oscillator loop. It is unnecessary to separately provide the filter loop. Accordingly, compared with the second embodiment, it is possible to simplify the circuit configuration. The third embodiment does not need any switch for controlling the center frequency of the frequency variable filter 1, which is inevitable in the second embodiment. The third embodiment can always filter the communication signal at optimal state. Furthermore, in the third embodiment, the output signal of the temperature-compensated crystal oscillator not shown is used as the reference signal. As a result, temperature drift of the oscillation frequency of the voltage control oscillator 41 and temperature drift of the center frequency of the frequency variable filter 1 can be compensated at the same time.

1. A filter control apparatus which controls a frequency variable filter capable of changing a center frequency and a transmission band width by controlling a capacitance of at least a portion of a plurality of voltage variable capacitors connected in series and parallel to resonators, comprising:
an input unit which inputs a reference signal with a predetermined reference frequency to the frequency variable filter; and
a filter control circuit which controls a center frequency and the transmission band width of the frequency variable filter by detecting a phase change generated when the reference signal passes through the frequency variable filter, and by variably controlling the capacitance of at least a portion of the voltage variable capacitor by using a control voltage in proportion to the phase change.

2. A filter control apparatus according to claim 1, wherein the input unit includes:
a first switching unit which selects whether to input a high frequency analog signal or to input the reference signal, to an input terminal of the frequency variable filter; and
a second switching unit which selects whether to supply a signal obtained by filtering the high frequency analog signal by the frequency variable filter to an output terminal or to supply a signal obtained by filtering the reference signal by the frequency variable filter to the filter control circuit.

3. A filter control apparatus according to claim 1; further comprising:
a voltage control oscillator which generates the reference signal; and
an oscillation control circuit which controls feedback signal so that a frequency of the reference signal coincides with a reference frequency,
wherein the filter control circuit and the oscillation control circuit have a phase shifter and a divider shared with each other.

4. A filter control apparatus according to claim 3, further comprising:
a coarse adjustment circuit which generates a coarse adjustment signal which adjusts coarsely the center frequency and the transmission band width of the frequency variable filter; and
an adjustment switching circuit which selects to supply the coarse adjustment voltage or to supply the output signal of the filter control circuit, to the frequency variable filter.

5. A filter control apparatus according to claim 1, further comprising a lock detecting circuit which controls the adjustment switching circuit so that the coarse adjustment voltage is supplied to the frequency variable filter until the oscillation frequency of the reference signal is stabilized, and the output voltage of the filter control circuit is supplied to the frequency variable filter after the oscillation frequency of the reference signal is stabilized.

6. A filter control apparatus according to claim 1, wherein the frequency variable filter includes:
at least one of a first voltage variable capacitor connected in parallel to the resonator, which has a first capacitance; and
at least one of a second voltage variable capacitor connected in series to the resonator, which has a second capacitance,
wherein the filter control circuit controls the capacitance of the first or second voltage variable capacitor.

7. A filter control apparatus according to claim 1, wherein the capacitance of the voltage variable capacitor connected in parallel to the resonator is variably controlled by the filter control circuit, and a capacitance of the voltage variable capacitor connected in series to the resonator is coarsely adjusted.

8. A filter control apparatus according to claim 1, wherein the frequency variable filter increases the capacitance of the voltage variable capacitor in order to narrow the passband and to move the center frequency transits in high frequency side, and decreases the capacitance of the voltage variable capacitor in order to enlarge the transmission band width and to move the center frequency in low frequency side.

9. A filter system, comprising:
a frequency variable filter capable of changing a center frequency and a transmission band width by controlling capacitances of a plurality of voltage variable capacitors connected in parallel and series to a resonator; and
a filter control circuit which controls a center frequency and the transmission band width of the frequency variable filter,
wherein the filter control circuit has a capacitance control circuit which controls the center frequency and the transmission band width of the frequency variable filter based on the capacitances of the plurality of voltage variable capacitors when a switching circuit, which selects whether to input a reference signal with a predetermined reference frequency into the frequency variable filter, or not, selects to input the reference signal into the frequency variable filter.

10. A filter system according to claim 9, wherein the input unit includes:
a first switching unit which selects whether to input a high frequency analog signal or to input the reference signal, to an input terminal of the frequency variable filter; and
a second switching unit which selects whether to supply a signal obtained by filtering the high frequency analog signal by the frequency variable filter to an output terminal or to supply a signal obtained by filtering the reference signal by the frequency variable filter to the filter control circuit.

11. A filter system according to claim 9, further comprising:
a voltage control oscillator which generates the reference signal; and
an oscillation control circuit which controls feedback signal so that a frequency of the reference signal coincides with a reference frequency,
wherein the filter control circuit and the oscillation control circuit have a phase shifter and a divider shared with each other.

12. A filter system according to claim 11, further comprising:
a coarse adjustment circuit which generates a coarse adjustment voltage which adjusts coarsely the center frequency and the transmission band width of the frequency variable filter; and
an adjustment switching circuit which switches to supply the coarse adjustment voltage or to supply the output voltage of the filter control circuit, to the frequency variable filter.

13. A filter system according to claim 9, further comprising a lock detecting circuit which controls the adjustment switching circuit so that the coarse adjustment voltage is supplied to the frequency variable filter until the oscillation frequency of the reference signal is stabilized, and the output voltage of the filter control circuit is supplied to the frequency variable filter after the oscillation frequency of the reference signal is stabilized.

14. A filter system according to claim 9, wherein the frequency variable filter includes:
at least one of a first voltage variable capacitor connected in parallel to the resonator, which has a first capacitance; and
at least one of a second voltage variable capacitor connected in series to the resonator, which has a second capacitance,
wherein the filter control circuit controls the capacitance of the first or second voltage variable capacitor.

15. A filter system according to claim 9, wherein the capacitance of the voltage variable capacitor connected in parallel to the resonator is variably controlled by the filter control circuit, and a capacitance of the voltage variable capacitor connected in series to the resonator is coarsely adjusted.

16. A filter system according to claim 9, wherein the frequency variable filter increases the capacitance of the voltage variable capacitor in order to narrow the passband and to move the center frequency transits in high frequency side, and decreases the capacitance of the voltage variable capacitor in order to enlarge the transmission band width and to move the center frequency in low frequency side.

17. A filter system, comprising:
a first frequency variable filter capable of changing a center frequency and transmission band width by controlling capacitances of a plurality of voltage variable capacitors connected in parallel and series to a resonator; and
a voltage control oscillator which has a second frequency variable filter having the same configuration as that of the first frequency variable filter; and
a phase locked loop circuit which generates a control voltage based on a phase difference between an oscillation output signal of the voltage control oscillator and a predetermined reference signal,
wherein the voltage control oscillator controls center frequencies and transmission band widths of the first and second frequency variable filters based on the same control voltage.

18. The filter system according to claim 17, wherein the voltage control oscillator controls the oscillation frequency based on the control voltage.

19. The filter system according to claim 17, wherein the frequency variable filter includes:
at least one of a first voltage variable capacitor connected in parallel to the piezoelectric resonator, which has a first capacitance; and
at least one of a second voltage variable capacitor connected in series to the piezoelectric resonator, which has a second capacitance,
wherein the filter control circuit controls the capacitance of the first or second voltage variable capacitor.

20. A filter system according to claim 17, wherein the capacitance of the voltage variable capacitor connected in parallel to the resonator is variably controlled by the filter control circuit, and a capacitance of the voltage variable capacitor connected in series to the resonator is coarsely adjusted.
